(19) United States
(12) Patent Application Publication
(10) Pub. No.: US 2017/0352565 A1
(43) Pub. Date: Dec. 7, 2017

(54) WORKPIECE CARRIER WITH GAS PRESSURE IN INNER CAVITIES

(71) Applicants: Chunlei Zhang, Saratoga, CA (US); Haitao Wang, Sunnyvale, CA (US); Kartik Ramaswamy, San Jose, CA (US); Vijay D. Parkhe, San Jose, CA (US); Jaeyong Cho, San Jose, CA (US)

(72) Inventors: Chunlei Zhang, Saratoga, CA (US); Haitao Wang, Sunnyvale, CA (US); Kartik Ramaswamy, San Jose, CA (US); Vijay D. Parkhe, San Jose, CA (US); Jaeyong Cho, San Jose, CA (US)

(21) Appl. No.: 15/364,589

(22) Filed: Nov. 30, 2016

Related U.S. Application Data
(60) Provisional application No. 62/352,695, filed on Jun. 21, 2016.
(60) Provisional application No. 62/346,764, filed on Jun. 7, 2016.

(51) Int. Cl. H01L 21/683; C23C 16/46; H01J 37/32; H01L 21/687; C23C 16/505; C23C 16/455; C23C 16/458; H01L 21/67

(52) U.S. Cl. CPC H01L 21/6833; C23C 16/4587; C23C 16/466; H01L 21/67069; H01L 21/68742; C23C 16/505; C23C 16/45565; H01J 37/32724; H01J 37/32697; H01L 21/67109; H01J 2237/2007; H01J 2237/3321; H01J 2237/2001

(57) ABSTRACT

A workpiece carrier suitable for high power processes is described. It may include a top plate to support a workpiece, a lift pin to lift a workpiece from a top plate, a lift pin hole through the top plate to contain the lift pin, and a connector to the lift pin hole to connect to a source of gas under pressure to deliver a cooling gas, for example helium, to the back side of the workpiece.

### CROSS-REFERENCE TO RELATED APPLICATIONS

The present application claims priority to prior U.S. Provisional Application Ser. No. 62/352,695 filed Jun. 21, 2016, entitled ELECTROSTATIC CHUCK WITH GAS PRESSURE APPLIED TO INNER CAVITIES by Chunlei Zhang, et al., the priority of which is hereby claimed and U.S. Provisional Application Ser. No. 62/346,764 filed Jun. 7, 2016, entitled ELECTROSTATIC CHUCK WITH GAS PRESSURE APPLIED TO INNER CAVITIES by Chunlei Zhang, et al., the priority of which is hereby claimed.

### FIELD

The present description relates to workpiece carriers for semiconductor and micromechanical processing and in particular to a carrier with gas pressure in inner cavities of the carrier.

### BACKGROUND

In the manufacture of semiconductor chips, a silicon wafer or other substrate is exposed to a variety of different processes in different processing chambers. The chambers may expose the wafer to a number of different chemical and physical processes whereby minute integrated circuits are created on the substrate. Layers of materials which make up the integrated circuit are created by processes including chemical vapor deposition, physical vapor deposition, epitaxial growth, and the like. Some of the layers of material are patterned using photoresist masks and wet or dry etching techniques. The substrates may be silicon, gallium arsenide, indium phosphide, glass, or other appropriate materials.

In these manufacturing processes, plasma may be used for depositing or etching various material layers. Plasma processing offers many advantages over thermal processing. For example, plasma enhanced chemical vapor deposition (PECVD) allows deposition processes to be performed at lower temperatures and at higher deposition rates than in analogous thermal processes. PECVD therefore allows material to be deposited at lower temperatures.

The processing chambers used in these processes typically include a substrate support, pedestal, or chuck disposed therein to support the substrate during processing. In some processes, the pedestal may include an embedded heater adapted to control the temperature of the substrate and/or provide elevated temperatures that may be used in the process.

HAR (High Aspect Ratio) plasma etch uses a significantly higher bias power to achieve bending free profiles. In order to support HAR for dielectric etching, the power may be increased to 20 KW, which brings significant impacts on an ESC (Electrostatic Chuck). Many current ESC designs cannot survive such a high voltage which comes as a direct result of a high bias power. Holes designed into an ESC may suffer in particular. Moreover, an ESC may experience bond failures in the lift pin area when excess radicals erode the bonds. Another impact is that the ESC surface temperature changes at a higher rate. The heating of the ESC surface is directly proportional to the applied RF plasma power. The heat may also be a result of bond failure. In addition bowing of the wafer carried on the ESC and the charge build up on the wafer also makes wafer de-chucking more difficult.

Common processes use an ESC to hold a wafer with 2 MHz 6.5 KW plasma power applied to the wafer for etching applications. High aspect ratio (e.g. 100:1) applications use much higher plasma powers. An ESC is described herein that operates with a low frequency high power plasma voltage to generate a high wafer bias. The higher power will increase failures of the ESC due to the dielectric breaking down and due to plasma ignition in gas holes that are designed into the ESC.

### SUMMARY

A workpiece carrier suitable for high power processes is described. It may include a top plate to support a workpiece, a lift pin to lift a workpiece from a top plate, a lift pin hole through the top plate to contain the lift pin, and a connector to the lift pin hole to connect to a source of gas under pressure to deliver a cooling gas, for example helium, to the back side of the workpiece.

### BRIEF DESCRIPTION OF THE DRAWINGS

Embodiments of the present invention are illustrated by way of example, and not limitation, in the figures of the accompanying drawings in which:

FIG. 1 is a diagram of a thermal image of an ESC during a process in a plasma processing chamber in accordance with an embodiment of the invention;

FIG. 2 is a top view diagram of a puck on a top plate of an ESC in accordance with an embodiment of the invention;

FIG. 3 is a partial cross-sectional side view diagram of an ESC with gas pressure in lift pin holes in accordance with an embodiment of the invention; and

FIG. 4 is a cross-sectional side view of a lift pin and lift pin hole in a top plate in accordance with an embodiment of the invention.

FIG. 5 is a diagram of a plasma etch system including a workpiece carrier in accordance with an embodiment of the present invention.

### DETAILED DESCRIPTION

The described ESC withstands high power and high bias voltages. The described inventive ESC may use a lift pin feature to deliver helium (He) for backside wafer cooling and may also control the lift pin cavity pressure. Many ESC's use a separate channel near the center of the top puck to deliver helium (He) to the backside of the wafer for cooling. The He is applied at pressure at the bottom of the ESC and is pushed up through the top plate or puck of the ESC to the space between the puck and the wafer back side. The He holes may experience arcing under high voltage (RF power). As described herein He holes in the ESC may be reduced or eliminated. Design features on the surface of the ESC are also minimized to improve temperature uniformity. This reduces local cold spots. The ESC cost is reduced and yet has improved reliability. In order to deliver He to the wafer back side, the lift pin holes may be used. These holes are open to the wafer back side to allow the lift pin to contact the wafer back side. He may be pressed though the hole around the lift pin to the space between the puck and the wafer back side.

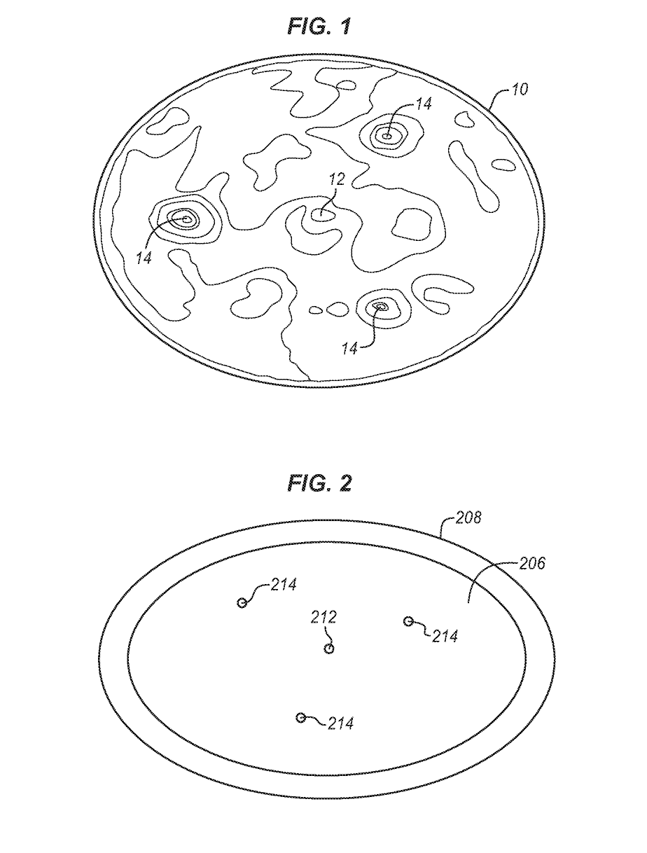

FIG. 1 is a diagram of a thermal image of an ESC 10 during a process in a plasma processing chamber. The central spot 12 corresponds to the location of the hole for helium cooling gases and the three peripheral spots 14 correspond to the location of the lift pin holes. As shown, the three lift pin areas get hotter because the bond is eroded locally. There are issues with the wafer processes in these hot spots and the bond between the puck and the support plate is eroded around the hot spots (lift pins). Pumping He through the three lift pin holes reduces the temperature differences at these locations, and also reduces the presence of radicals near the lift pins to erode the bonding materials that hold the top plate to the rest of the ESC.

There is a cavity around the lift pins within the lift pin holes to allow the lift pins to move. The lift pins push the wafer off the puck when the wafer is to be moved to another position. The arcing is prevented by raising the lift pin cavity with a controlled high pressure. He is a suitable gas to be applied to the lift pin cavity because of its electrical characteristics and thermal conductivity and because, in many ESC's, it is already used against the wafer back side through He holes. The radical buildup of reaction gases in the lift pin cavity is avoided which reduces bond erosion. By filling the lift pin holes with He, there is no longer any need to pump reaction gases out of the lift pin holes. Pressure equalization is also not required for the lift pin holes which provides for further cost reduction. In addition, with this He pressure approach, the wafer will not be held to the chuck by a vacuum that is caused when the chuck cools. The helium pressure will prevent such a vacuum. This simplifies de-chucking the wafer.

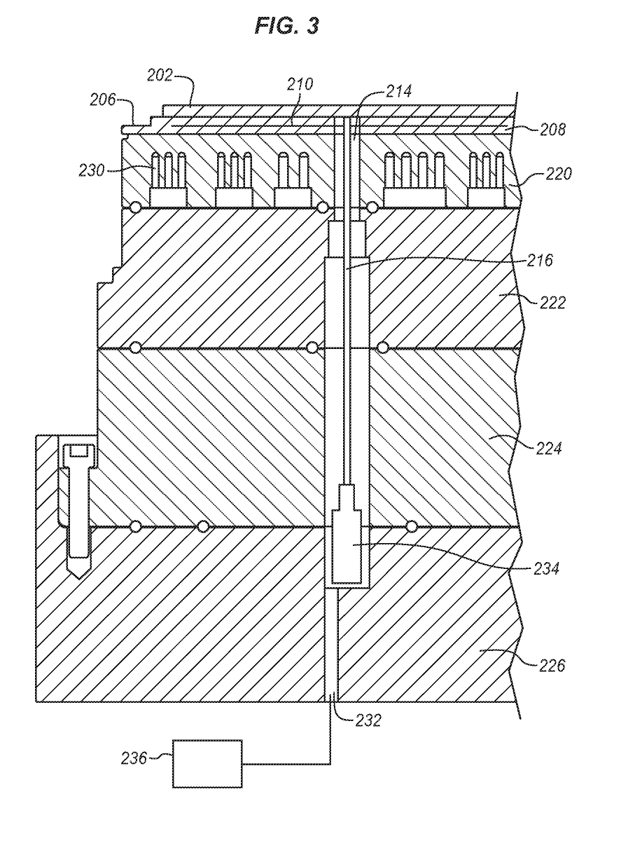

FIG. 2 is a top view diagram of a puck 206 on a top plate of an ESC. The puck has an inner electrode 210 of FIG. 3 to hold a wafer (not shown). The electrode is beneath a dielectric layer and is sized to be almost the same size as the wafer that it will hold. The electrode is electrically connected to a DC voltage source.

There is an optional central gas hole 212 and an array of lift pin holes 214. The gas hole allows additional cooling gas to be pushed out to the space between the wafer and the puck. The lift pin holes allow lift pins to extend through the holes to push a wafer off the chuck (de-chucking) so that the wafer may be removed for other or additional processing. There may be additional holes and other structures to perform other functions. Heaters, cooling channels, plasma process structures and other components are not shown in order not to obscure the drawing figure.

FIG. 3 is a partial cross-sectional side view diagram of an ESC showing the top layer 208 and puck 206 of FIG. 2. The top plate is configured to carry a workpiece 202 such as a silicon wafer or other item. The workpiece, in this example is held by an electrostatic force generated by electrodes (not shown) in the top plate. The top plate is formed of a dielectric material such as a ceramic like aluminum nitride and is mounted to a base plate 220 using, for example, an adhesive. The base plate may be formed of any suitable material, such as aluminum, to support the top plate. The base plate may contain cooling channels 230, wiring layers, pipes, tubes, and other structures (not shown) to support the puck and a wafer 202 that is attached to and carried by the puck.

The base plate is supported by a ground plate 224 that is carried by a support plate 226. An insulation plate 222 formed of an electrical and thermal isolator such as Rexolite®, or another plastic or polystyrene, heat resistant material to isolate the base cooling plate from the lower ground and support plates. The bottom support plate provides fittings for electrical and gas connections and provides attachment points for carriers and other fittings.

The lift pin hole 214 extends through the top plate 208, the base plate 220, the insulation plate 222, the ground plate 224 and the support plate 226 to connect to a gas line 232 that supplies gas under pressure. The gas is supplied to the gas line by a regulated cooling gas source 236 such as a tank and pump or any other type of source. The gas line supplies the gas from the gas line to each lift pin hole through a connector in the support plate for each of the lift pin holes. The connector is at the bottom of the support plate or any other suitable plate at the interface between the plate and the external environment. There may also be additional connectors for any additional gas holes. Alternatively, the support plate may use a single connector into a manifold within the support plate or another plate to supply gas to each of the lift pin holes. As mentioned above, the cooling gas may be helium, nitrogen, or any other suitable inert gas with a high thermal conductivity. A gas hole has the same or a similar appearance and the illustrated hole represents both a lift pin hole and a gas hole.

The lift pin 216 is carried and guided through the center of the hole and extends from an actuator 234. The lift pin assembly is used to lift and lower a workpiece or other substrate, such as a silicon wafer onto the electrostatic chuck puck 206. The actuator may take any of a variety of different forms. In addition, the relative positions of the lift pin and actuator may be adjusted to accommodate different configurations.

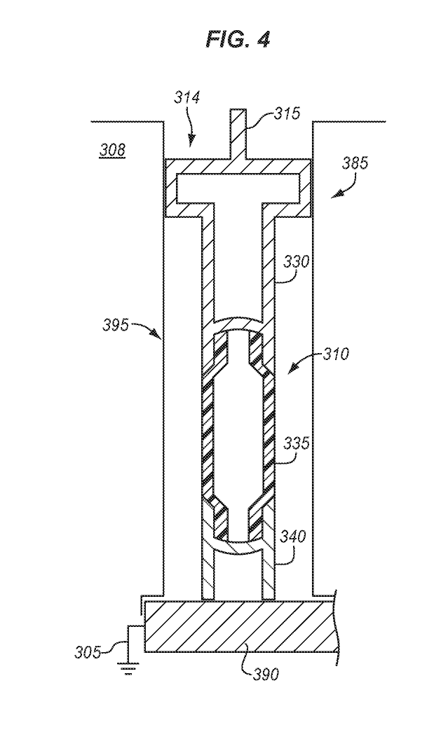

FIG. 4 is a cross-sectional view of a lift pin and lift pin hole in a top plate. Lift pins 395 are suitable for de-chucking a substrate and are mounted in lift pin holes 314. The lift pins overcome a vacuum and any residual electrostatic charge, through the use of physical pressure and a current sink 305. The lift pin hole 214 is coupled to a gas line as shown in FIG. 3, but not shown here in order not to obscure the lift pin. The illustrated example is one configuration for a lift pin 395, however, the lift pin may take any of a variety of other forms to suit other ESC configurations. The drawing figure is to show just one example of a lift pin for use in the example of FIG. 3.

Generally, the lift pins 395 comprise movable elongated members 310 having tips 315 suitable for lifting and lowering the substrate off the chuck. At least one lift pin 395 is capable of forming an electrically conductive path between the substrate and the current sink 305. A voltage reducer or a current limiter may be coupled in series with the electrically conductive path of the elongated member 310. The voltage reducer operates by reducing the voltage caused by RF currents used to form a plasma and attract the plasma to the substrate, while the current limiter operates by limiting the flow of the RF currents flowing therethrough.

To de-chuck a substrate held to the ESC by low frequency electrostatic residual charge, the lift pins 395 are raised and electrically contacted against the substrate. The substrate is lifted off the chuck after the residual electrostatic charge in the substrate is substantially discharged.

In a preferred configuration, each of the lift pins 395 have an elongated member 310 with an electrically conductive upper portion 330 that has a tip 315 suitable for lifting and lowering the substrate. A central portion 335 has a voltage reducer or a current limiter, and an electrically conductive lower portion 340 is suitable for electrical connection to the current sink 305. The electrically conductive upper portion 330 and lower portion 340 are made from metals or other rigid conductive materials having low resistance to current flow. The upper portion 330 can also comprise a layer of a flexible material that prevents damage to the substrate when the lift pin tip 315 is pushed upwardly against the substrate.

In one example, the actuator 234 is a support 390, such as a C-shaped ring around the support plate. The support may contact a plurality of lift pins 395 mounted around the support. Preferably, at least three, and more preferably four lift pins (not shown) are mounted symmetrically on the support so that the substrate 202 can be lifted off the chuck 206 by a uniformly applied pressure. Such a support may be attached to a lift bellows that can lift and lower the support, thereby lifting and lowering the lift pins 395 through the holes 314.

Gas may be delivered to the back side of the wafer between the top surface of the pedestal and the wafer to improve heat convection between the wafer and the pedestal. An effective radial gas flow improves gas flow across the back side of the wafer. The gas may be pumped through a channel in the base of the pedestal assembly to the top of the pedestal. The channel may include the lift pin holes. A mass flow controller may be used to control the flow through the pedestal. In a vacuum or chemical deposition chamber, the backside gas provides a medium for heat transfer for heating and cooling of the wafer during processing.

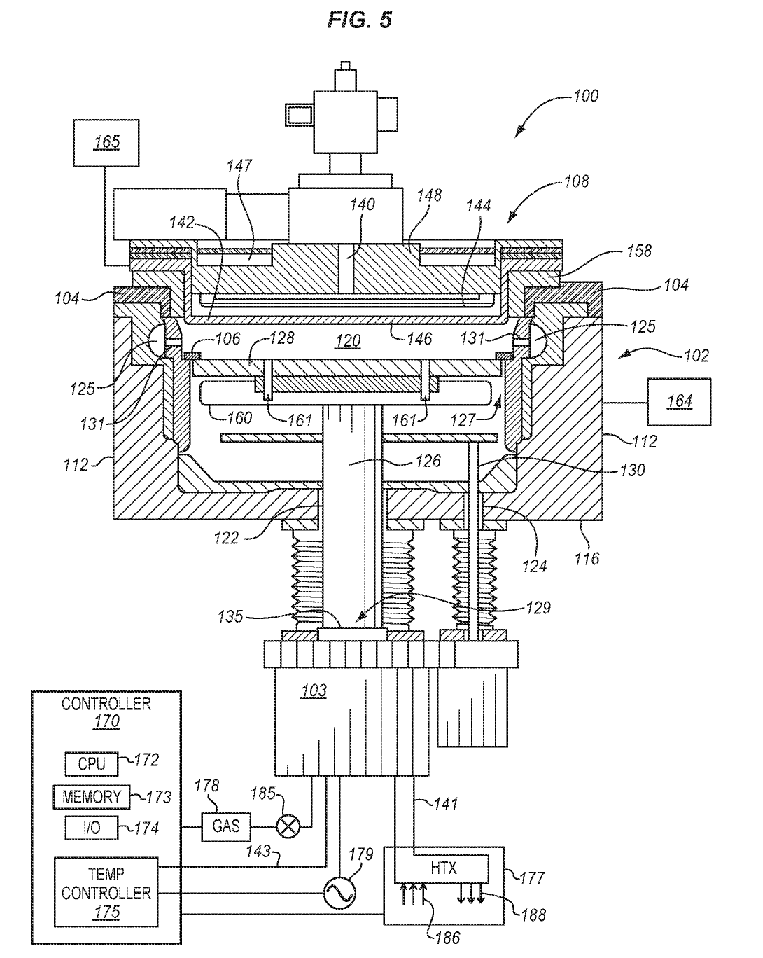

FIG. 5 is a partial cross sectional view of a plasma system 100 having a pedestal 128 according to embodiments described herein. The pedestal 128 has an active cooling system which allows for active control of the temperature of a substrate positioned on the pedestal over a wide temperature range while the substrate is subjected to numerous process and chamber conditions. The plasma system 100 includes a processing chamber body 102 having sidewalls 112 and a bottom wall 116 defining a processing region 120.

A pedestal, carrier, chuck or ESC 128 is disposed in the processing region 120 through a passage 122 formed in the bottom wall 116 in the system 100. The pedestal 128 is adapted to support a substrate (not shown) on its upper surface. The substrate may be any of a variety of different workpieces for the processing applied by the chamber 100 made of any of a variety of different materials. The pedestal 128 may optionally include heating elements (not shown), for example resistive elements, to heat and control the substrate temperature at a desired process temperature. Alternatively, the pedestal 128 may be heated by a remote heating element, such as a lamp assembly.

The pedestal 128 is coupled by a shaft 126 to a power outlet or power box 103, which may include a drive system that controls the elevation and movement of the pedestal 128 within the processing region 120. The shaft 126 also contains electrical power interfaces to provide electrical power to the pedestal 128. The power box 103 also includes interfaces for electrical power and temperature indicators, such as a thermocouple interface. The shaft 126 also includes a base assembly 129 adapted to detachably couple to the power box 103. A circumferential ring 135 is shown above the power box 103. In one embodiment, the circumferential ring 135 is a shoulder adapted as a mechanical stop or land configured to provide a mechanical interface between the base assembly 129 and the upper surface of the power box 103.

A rod 130 is disposed through a passage 124 formed in the bottom wall 116 and is used to activate substrate lift pins 161 disposed through the pedestal 128. The substrate lift pins 161 lift the workpiece off the pedestal top surface to allow the workpiece to be removed and taken in and out of the chamber, typically using a robot (not shown) through a substrate transfer port 160.

A chamber lid 104 is coupled to a top portion of the chamber body 102. The lid 104 accommodates one or more gas distribution systems 108 coupled thereto. The gas distribution system 108 includes a gas inlet passage 140 which delivers reactant and cleaning gases through a showerhead assembly 142 into the processing region 120B. The showerhead assembly 142 includes an annular base plate 148 having a blocker plate 144 disposed intermediate to a faceplate 146.

A radio frequency (RF) source 165 is coupled to the showerhead assembly 142. The RF source 165 powers the showerhead assembly 142 to facilitate generation of plasma between the faceplate 146 of the showerhead assembly 142 and the heated pedestal 128. In one embodiment, the RF source 165 may be a high frequency radio frequency (HFRF) power source, such as a 13.56 MHz RF generator. In another embodiment, RF source 165 may include a HFRF power source and a low frequency radio frequency (LFRF) power source, such as a 300 kHz RF generator. Alternatively, the RF source may be coupled to other portions of the processing chamber body 102, such as the pedestal 128, to facilitate plasma generation. A dielectric isolator 158 is disposed between the lid 104 and showerhead assembly 142 to prevent conducting RF power to the lid 104. A shadow ring 106 may be disposed on the periphery of the pedestal 128 that engages the substrate at a desired elevation of the pedestal 128.

Optionally, a cooling channel 147 is formed in the annular base plate 148 of the gas distribution system 108 to cool the annular base plate 148 during operation. A heat transfer fluid, such as water, ethylene glycol, a gas, or the like, may be circulated through the cooling channel 147 such that the base plate 148 is maintained at a predefined temperature.

A chamber liner assembly 127 is disposed within the processing region 120 in very close proximity to the sidewalls 101, 112 of the chamber body 102 to prevent exposure of the sidewalls 101, 112 to the processing environment within the processing region 120. The liner assembly 127 includes a circumferential pumping cavity 125 that is coupled to a pumping system 164 configured to exhaust gases and byproducts from the processing region 120 and control the pressure within the processing region 120. A plurality of exhaust ports 131 may be formed on the chamber liner assembly 127. The exhaust ports 131 are configured to allow the flow of gases from the processing region 120 to the circumferential pumping cavity 125 in a manner that promotes processing within the system 100.

A system controller 170 is coupled to a variety of different systems to control a fabrication process in the chamber. The controller 170 may include a temperature controller 175 to execute temperature control algorithms (e.g., temperature feedback control) and may be either software or hardware or a combination of both software and hardware. The system controller 170 also includes a central processing unit 172, memory 173 and input/output interface 174. The temperature controller receives a temperature reading 143 from a sensor (not shown) on the pedestal. The temperature sensor may be proximate a coolant channel, proximate the wafer, or placed in the dielectric material of the pedestal. The temperature controller 175 uses the sensed temperature or temperatures to output control signals affecting the rate of heat transfer between the pedestal assembly 142 and a heat source and/or heat sink external to the plasma chamber 105, such as a heat exchanger 177.

The system may also include a controlled heat transfer fluid loop 141 with flow controlled based on the temperature feedback loop. In the example embodiment, the temperature controller 175 is coupled to a heat exchanger (HTX)/chiller 177. Heat transfer fluid flows through a valve (not shown) at a rate controlled by the valve through the heat transfer fluid loop 141. The valve may be incorporate into the heat exchanger or into a pump inside or outside of the heat exchanger to control the flow rate of the thermal fluid. The heat transfer fluid flows through conduits in the pedestal assembly 142 and then returns to the HTX 177. The temperature of the heat transfer fluid is increased or decreased by the HTX and then the fluid is returned through the loop back to the pedestal assembly.

The HTX includes a heater 186 to heat the heat transfer fluid and thereby heat the substrate. The heater may be formed using resistive coils around a pipe within the heat exchanger or with a heat exchanger in which a heated fluid conducts heat through an exchanger to a conduit containing the thermal fluid. The HTX also includes a cooler 188 which draws heat from the thermal fluid. This may be done using a radiator to dump heat into the ambient air or into a coolant fluid or in any of a variety of other ways. The heater and the cooler may be combined so that a temperature controlled fluid is first heated or cooled and then the heat of the control fluid is exchanged with that of the thermal fluid in the heat transfer fluid loop.

The valve (or other flow control devices) between the HTX 177 and fluid conduits in the pedestal assembly 142 may be controlled by the temperature controller 175 to control a rate of flow of the heat transfer fluid to the fluid loop. The temperature controller 175, the temperature sensor, and the valve may be combined in order to simplify construction and operation. In embodiments, the heat exchanger senses the temperature of the heat transfer fluid after it returns from the fluid conduit and either heats or cools the heat transfer fluid based on the temperature of the fluid and the desired temperature for the operational state of the chamber 102.

Electric heaters (not shown) may also be used in the pedestal assembly to apply heat to the pedestal assembly. The electric heaters, typically in the form of resistive elements are coupled to a power supply 179 that is controlled by the temperature control system 175 to energize the heater elements to obtain a desired temperature.

The heat transfer fluid may be a liquid, such as, but not limited to deionized water/ethylene glycol, a fluorinated coolant such as Fluorinert® from 3M or Galden® from Solvay Solexis, Inc. or any other suitable dielectric fluid such as those containing perfluorinated inert polyethers. While the present description describes the pedestal in the context of a PECVD processing chamber, the pedestal described herein may be used in a variety of different chambers and for a variety of different processes.

A backside gas source 178 such as a pressurized gas supply or a pump and gas reservoir are coupled to the chuck assembly 142 through a mass flow meter 185 or other type of valve. The backside gas may be helium, argon, or any gas that provides heat convection and/or cooling between the wafer and the puck without affecting the processes of the chamber. The gas source pumps gas through a gas outlet of the pedestal assembly described in more detail above through lift pin holes and any gas holes to the back side of the wafer under the control of the system controller 170 to which the system is connected.

The processing system 100 may also include other systems, not specifically shown in FIG. 1, such as plasma sources, vacuum pump systems, access doors, micromachining, laser systems, and automated handling systems, inter alia. The illustrated chamber is provided as an example and any of a variety of other chambers may be used with the present invention, depending on the nature of the workpiece and desired processes. The described pedestal and thermal fluid control system may be adapted for use with different physical chambers and processes.

As used in this description and the appended claims, the singular forms “a”, “an” and “the” are intended to include the plural forms as well, unless the context clearly indicates otherwise. It will also be understood that the term “and/or” as used herein refers to and encompasses any and all possible combinations of one or more of the associated listed items.

The terms “coupled” and “connected,” along with their derivatives, may be used herein to describe functional or structural relationships between components. It should be understood that these terms are not intended as synonyms for each other. Rather, in particular embodiments, “connected” may be used to indicate that two or more elements are in direct physical, optical, or electrical contact with each other. “Coupled” my be used to indicate that two or more elements are in either direct or indirect (with other intervening elements between them) physical, optical, or electrical contact with each other, and/or that the two or more elements co-operate or interact with each other (e.g., as in a cause an effect relationship).

The terms “over,” “under,” “between,” and “on” as used herein refer to a relative position of one component or material layer with respect to other components or layers where such physical relationships are noteworthy. For example in the context of material layers, one layer disposed over or under another layer may be directly in contact with the other layer or may have one or more intervening layers. Moreover, one layer disposed between two layers may be directly in contact with the two layers or may have one or more intervening layers. In contrast, a first layer “on” a second layer is in direct contact with that second layer. Similar distinctions are to be made in the context of component assemblies.

It is to be understood that the above description is intended to be illustrative, and not restrictive. For example, while flow diagrams in the figures show a particular order of operations performed by certain embodiments of the invention, it should be understood that such order is not required (e.g., alternative embodiments may perform the operations in a different order, combine certain operations, overlap certain operations, etc.). Furthermore, many other embodiments will be apparent to those of skill in the art upon reading and understanding the above description. Although the present invention has been described with reference to specific exemplary embodiments, it will be recognized that the invention is not limited to the embodiments described, but can be practiced with modification and alteration within the spirit and scope of the appended claims. The scope of the invention should, therefore, be determined with reference to the appended claims, along with the full scope of equivalents to which such claims are entitled.

Examples of different embodiments of the gas pressure ESC include an ESC that uses a lift pin feature to deliver a cooling gas, for example helium, for backside wafer cooling.

Embodiments include the design above wherein the helium is applied at pressure at the bottom of the ESC and is pushed up through the top plate or puck of the ESC to the space between the puck and the back side of the wafer through the lift pin holes.

Embodiments include the design above wherein helium is pressed though the lift pin hole around the lift pin to the space between the puck and the wafer back side

Embodiments include the design above wherein the helium holes in the ESC are reduced or eliminated by using lift pin holes to apply the cooling gas.

Embodiments include the design above in which the lift pin cavity pressure is controlled, for example using an external regulated helium pump.

Embodiments include the design above in which the lift pin holes are filled with helium.

Embodiments include means for performing any of the functions or operations of the design above.

Embodiments include a method for processing a workpiece using an electrostatic chuck with a top plate and lift pins to lift the workpiece off the top plate, the method including conveying a cooling gas through lift pin holes to the back side of the wafer.

What is claimed is:

1. A workpiece carrier comprising:
a top plate to support a workpiece;
a lift pin to lift a workpiece from a top plate;
a lift pin hole through the top plate to contain the lift pin; and
a connector to the lift pin hole to connect to a source of gas under pressure to deliver a cooling gas to the back side of the workpiece.

2. The carrier of claim 1, wherein the cooling gas is applied at pressure at the bottom of the carrier and is pushed up through the top plate of the carrier to a space between the top plate and the back side of the wafer through the lift pin holes.

3. The carrier of claim 1, further comprising a cooling plate below the top plate attached to the top plate with an adhesive and wherein the lift pin hole extends through the cooling plate.

4. The carrier of claim 3, wherein the cooling plate is metal and the top plate is ceramic, the metal having a different coefficient of thermal expansion from the ceramic.

5. The carrier of claim 1, wherein the top plate includes an electrode to apply an electrostatic force to grip the workpiece.

6. The carrier of claim 1, wherein the top plate has a central hole to apply a cooling gas to the workpiece.

7. The carrier of claim 1, further comprising a support plate below the cooling plate, the support plate configured to connect to a gas line to supply the gas under pressure to the lift pin hole.

8. The carrier of claim 7, further comprising a lift pin actuator in the lift pin hole in the support plate to drive the lift pin to lift the workpiece.

9. The carrier of claim 1, wherein the top plate has no central helium hole.

10. The carrier of claim 1, wherein the source of gas under pressure comprises an external regulated helium pump.

11. A method of processing a workpiece using a workpiece carrier, the method comprising:
attaching a workpiece to the carrier using an electrostatic charge on an electrode;
placing the carrier into a plasma processing chamber with the workpiece attached;
conveying a cooling gas through lift pin holes of a top plate of the carrier to the back side of the workpiece during a plasma process in the plasma processing chamber;
releasing the electrostatic charge on the electrode after the plasma process; and
de-chucking the workpiece by extending the lift pins through the lift pin holes to push against the back side of the workpiece.

12. The method of claim 11, wherein conveying cooling gas comprises applying the cooling gas at pressure at a support plate of the carrier and pushing the cooling gas up through a top plate of the carrier, wherein the top plate contacts the workpiece, to a space between the top plate and the back side of the workpiece through the lift pin holes.

13. The method of claim 11, further comprising conveying the cooling gas through a central gas hole in the workpiece.

14. The method of claim 11, wherein conveying a cooling gas comprises operating an external regulated helium pump coupled to the lift pin holes through a gas line.

15. A plasma processing chamber comprising:
a plasma chamber;
a plasma source to generate a plasma containing gas ions in the plasma chamber; and
a workpiece carrier to carry a workpiece for processing within the chamber, the carrier having a top plate to support a workpiece, a lift pin to lift a workpiece from a top plate, a lift pin hole through the top plate to contain the lift pin, and a connector to the lift pin hole to connect to a source of gas under pressure to deliver a cooling gas to the back side of the workpiece.

16. The chamber of claim 15, the carrier further comprising a support plate below the cooling plate, the support plate configured to connect to a gas line to supply the gas under pressure to the lift pin hole.

17. The chamber of claim 16, the carrier further comprising a lift pin actuator in the lift pin hole in the support plate to drive the lift pin to lift the workpiece.

18. The chamber of claim 15, wherein the top plate includes an electrode to apply an electrostatic force to grip the workpiece.

19. The chamber of claim 15, wherein the top plate does not have a central hole to apply a cooling gas to the workpiece.
